(19) United States
(12) Patent Application Publication
(10) Pub. No.: US 2013/0019904 A1
(43) Pub. Date: Jan. 24, 2013

(54) BATCH CLEANING APPARATUS AND METHOD FOR BATCH CLEANING PRINTED CIRCUIT BOARDS

(71) Applicants: Eric Wayne Becker, Lebanon, MO (US); John Neiderman, Camdenton, MO (US)

(72) Inventors: Eric Wayne Becker, Lebanon, MO (US); John Neiderman, Camdenton, MO (US)

(73) Assignee: Illinois Tool Works Inc., Glenview, IL (US)

(21) Appl. No.: 13/186,683

(22) Filed: Jul. 20, 2011

(51) Int. Cl. B08B 3/02; H05K 3/22

(52) U.S. Cl. 134/25.5; 134/199; 134/145; 134/195; 134/58 R

(57) ABSTRACT

A batch cleaning apparatus includes a housing including a process chamber, a fluid holding tank supported by the housing, and a fluid delivery manifold assembly removably disposed in the process chamber of the housing and in fluid communication with fluid holding tank. The fluid delivery manifold assembly includes a fluid inlet port selectively coupled to the fluid holding tank, a plurality of distribution manifolds in fluid communication with the fluid inlet port, and a plurality of spray bars in fluid communication with the distribution manifolds. The spray bars are configured to provide support for printed circuit boards during a cleaning operation. Other embodiments of batch cleaning apparatus and methods of batch cleaning are further disclosed.

### BACKGROUND OF THE INVENTION

1. Field of the Disclosure

This application relates generally to an apparatus for cleaning printed circuit boards and, more particularly, to a liquid delivery system of a batch cleaning apparatus and method to deliver liquid to printed circuit boards for cleaning.

2. Discussion of Related Art

Various types of liquid cleaning apparatus are used to clean printed circuit boards for removal of contaminates, such as flux residues, resins and the like. These contaminates remain on the printed circuit board from the soldering process. Batch cleaners typically incorporate rotating spray manifolds positioned above and below the printed circuit board assemblies or substrates located in a basket or a rack.

The soldering process has recently advanced in two significant ways—the transition from tin-lead solder to lead-free materials and the reduction in the size of printed circuit board assembly and the associated increase in the density of smaller, low-profile components. These new soldering materials have increased temperature requirements for soldering and are typically formulated to have higher flux content by weight. The combination of lead-free processes and new printed circuit board designs are demanding more time and energy to meet industry cleanliness standards. The importance of reducing cleaning cycle times and cleaning residue from underneath low-profile, densely populated components has driven the optimization of batch cleaning equipment using basket or rack manifold cleaning systems for efficient fluid dynamics providing reduced cycle times while maintaining industry standard cleanliness.

Additionally, during cleaning, fluid deflection and/or component shadowing can result in insufficient cleaning and removal of residues from the printed circuit boards. These remaining residues create defects during assembly, thereby resulting in rework and/or scrap, which can be extremely costly to a printed circuit board manufacturer. Moreover, residue remaining on printed circuit boards can be ionic in nature and create reliability issues or field failures. The results of these failures are not only costly but in mission-critical applications can pose a risk upon failure.

### BRIEF SUMMARY OF THE INVENTION

One aspect of the disclosure is directed to a batch cleaning apparatus for cleaning printed circuit boards. In one embodiment, the batch cleaning apparatus comprises a housing including a process chamber, a fluid holding tank supported by the housing, and a fluid delivery manifold assembly removably disposed in the process chamber of the housing and in fluid communication with fluid holding tank. The fluid delivery manifold assembly includes a fluid inlet port selectively coupled to the fluid holding tank, a plurality of distribution manifolds in fluid communication with the fluid inlet port, and a plurality of spray bars in fluid communication with the distribution manifolds. The spray bars are configured to provide support for printed circuit boards during a cleaning operation.

Embodiments of the batch cleaning apparatus may include configuring the fluid delivery manifold assembly with a base and a handle secured to the base. The handle is configured to move the fluid delivery manifold assembly. The fluid delivery manifold assembly further may include a plurality of rollers secured to the base and configured to roll the fluid delivery manifold assembly into and out of the process chamber. The spray bars may be positioned directly in front of and behind the printed circuit boards to provide a direct fluid path to the printed circuit boards during operation of the batch cleaning apparatus. Orifices of spray bars of an outer row of spray bars may be located on one side of the spray bars. Orifices of spray bars of an inner row of spray bars may be located on both sides of the spray bars. The batch cleaning apparatus further may comprise one or more of the following components: a slip fit manifold coupler connected to and in fluid communication with the fluid inlet port of the fluid delivery manifold assembly; a pump to provide movement of fluid from the fluid holding tank to the fluid delivery manifold assembly; and an electromechanical control system to control the operation of the batch cleaning apparatus.

Another aspect of the disclosure is directed to a method of batch cleaning printed circuit boards. In one embodiment, the method comprises providing a batch cleaning apparatus including a housing including a process chamber, a fluid holding tank supported by the housing, and a fluid delivery manifold assembly removably disposed in the process chamber of the housing and in fluid communication with fluid holding tank. The fluid delivery manifold assembly includes a fluid inlet port selectively coupled to the fluid holding tank, a plurality of distribution manifolds in fluid communication with the inlet port, and a plurality of spray bars in fluid communication with the distribution manifolds. The spray bars are configured to provide support for printed circuit boards during a cleaning operation. The method further comprises: loading printed circuit boards on the fluid delivery manifold assembly in a position in which the printed circuit boards are positioned between the spray bars; and performing a batch cleaning operation.

Embodiments of the method further may comprise rolling the fluid delivery manifold assembly into the process chamber after loading printed circuit boards, and/or rolling the fluid delivery manifold assembly out of the process chamber after performing the batch cleaning operation. Orifices of the spray bars of an outer row of spray bars may be located on one side of the spray bars and orifices of the spray bars of an inner row of spray bars have orifices located on both sides of the spray bars. The method further may comprise positioning the spray bars directly in front of and behind the printed circuit boards to provide a direct fluid path to the printed circuit boards, and/or connecting the fluid delivery manifold assembly to the fluid holding tank by a slip fit manifold coupler.

A further aspect of the disclosure is directed to a batch cleaning apparatus comprising a housing including a process chamber, a fluid holding tank supported by the housing, and a fluid delivery manifold assembly removably disposed in the process chamber of the housing and in fluid communication with fluid holding tank. The fluid delivery manifold assembly includes a base and a handled secured to the base and configured to lift the fluid delivery manifold assembly, a plurality of distribution manifolds supported by the base, a fluid inlet port selectively coupled to the fluid holding tank and in fluid communication with the plurality of distribution manifolds, and a plurality of spray bars in fluid communication with the distribution manifolds.

Embodiments of the batch cleaning apparatus may include configuring the spray bars of the fluid delivery manifold assembly to provide support for printed circuit boards during a cleaning operation. The fluid delivery manifold assembly further may include a plurality of rollers secured to the base and configured to roll the fluid delivery manifold assembly out of the process chamber. The batch cleaning apparatus further may comprises a slip fit manifold coupler connected to and in fluid communication with the fluid inlet port of the fluid delivery manifold assembly.

### BRIEF DESCRIPTION OF THE DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a front perspective view of a batch cleaning apparatus of an embodiment of the disclosure;

FIG. 2 is a rear perspective view of a fluid delivery manifold assembly of the batch cleaning apparatus of FIG. 1;

FIG. 3 is a front perspective view of the fluid delivery manifold assembly illustrated in

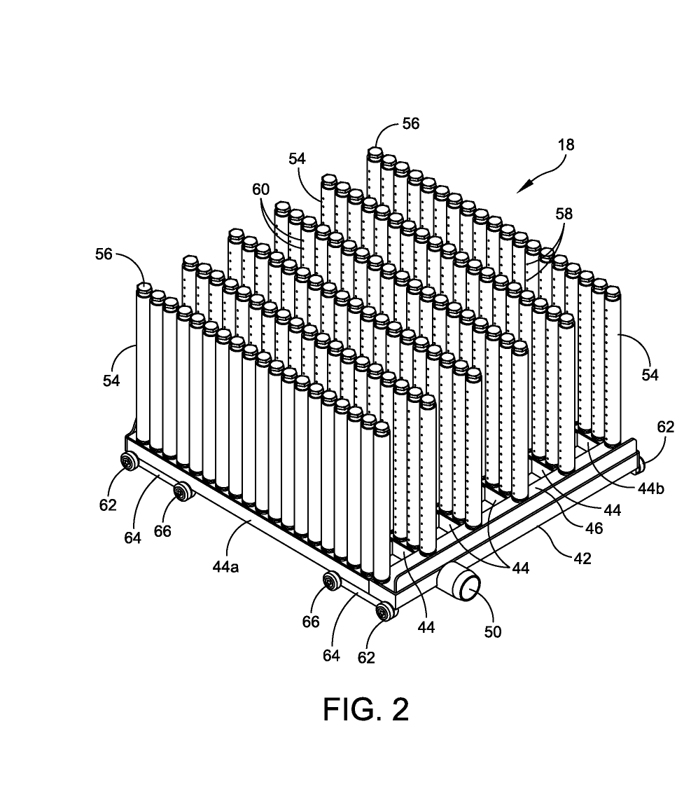

FIG. 2 supporting printed circuit boards;

FIG. 4 is an exploded perspective view of a slip fit manifold coupler;

FIGS. 5A and 5B are photographs showing exemplary substrates before and after cleaning; and

FIGS. 6A and 6B are photographs showing exemplary substrates before and after cleaning.

### DETAILED DESCRIPTION OF THE INVENTION

For the purposes of illustration only, and not to limit the generality, the present disclosure will now be described in detail with reference to the accompanying figures. This disclosure is not limited in its application to the details of construction and the arrangement of components set forth in the following description or illustrated in the drawings. The principles set forth in this disclosure are capable of other embodiments and of being practiced or carried out in various ways. Also the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

Solder paste is routinely used in the assembly of printed circuit boards, where the solder paste is used to join electronic components to the circuit board. Solder paste includes solder for joint formation and flux for preparing metal surfaces for solder attachment. The solder paste may be deposited onto the metal surfaces (e.g., electronic pads) provided on the circuit board by using any number of application methods. In one example, a stencil printer may employ a squeegee to force the solder paste through a metallic stencil laid over an exposed circuit board surface. In another example, a dispenser may dispense solder paste material onto specific areas of the circuit board. Leads of an electronic component are aligned with and impressed into the solder deposits to form the assembly. In reflow soldering processes, the solder is then heated to a temperature sufficient to melt the solder and cooled to permanently couple the electronic component, both electrically and mechanically, to the circuit board. The solder typically includes an alloy having a melting temperature lower than that of the metal surfaces to be joined. The temperature also must be sufficiently low so as to not cause damage to the electronic component. In certain embodiments, the solder may be a tin-lead alloy. However, solders employing lead-free materials may also be used. Another process to attach components onto printed circuit boards is a wave soldering process.

In the solder, the flux typically includes a vehicle, solvent, activators and other additives. The vehicle is a solid or nonvolatile liquid that coats the surface to be soldered and can include rosin, resins, glycols, polyglycols, polyglycol surfactants, and glycerine. The solvent, which evaporates during the pre-heat and soldering process, serves to dissolve the vehicle activators, and other additives. Examples of typical solvents include alcohols, glycols, glycol esters and/or glycol ethers and water. The activator enhances the removal of metal oxide from the surfaces to be soldered. Common activators include amine hydrochlorides, dicarboxylic acids, such as adipic or succinic acid, and organic acids, such as citric, malic or abietic acid. Other flux additives can include surfactants, viscosity modifiers and additives for providing low slump or good tack characteristics for holding the components in place before reflow.

As mentioned above, the soldering processes described herein demand that the printed circuit boards be cleaned prior to being released for use. Batch cleaners, sometimes referred to as batch spray in air printed circuit board cleaning equipment, typically incorporate rotating spray manifolds that are positioned above and below printed circuit boards or assemblies located in a separate basket or a rack. The circuit boards are loaded into a pronged basket or rack of the batch cleaner, which is designed to hold the circuit boards in a semi-vertical position while the manifolds direct fluid and air toward the substrate during a cleaning operation. The batch cleaner disclosed herein is designed to optimize the manner in which fluid and air is directed to the circuit boards for cleaning and drying by adopting a design in which spray bars function to hold the circuit boards in place. In addition, the fluid delivery manifold assembly can be easily inserted into and removed from a process chamber of a housing of the batch cleaner for easy access to load and unload circuit boards from the batch cleaner.

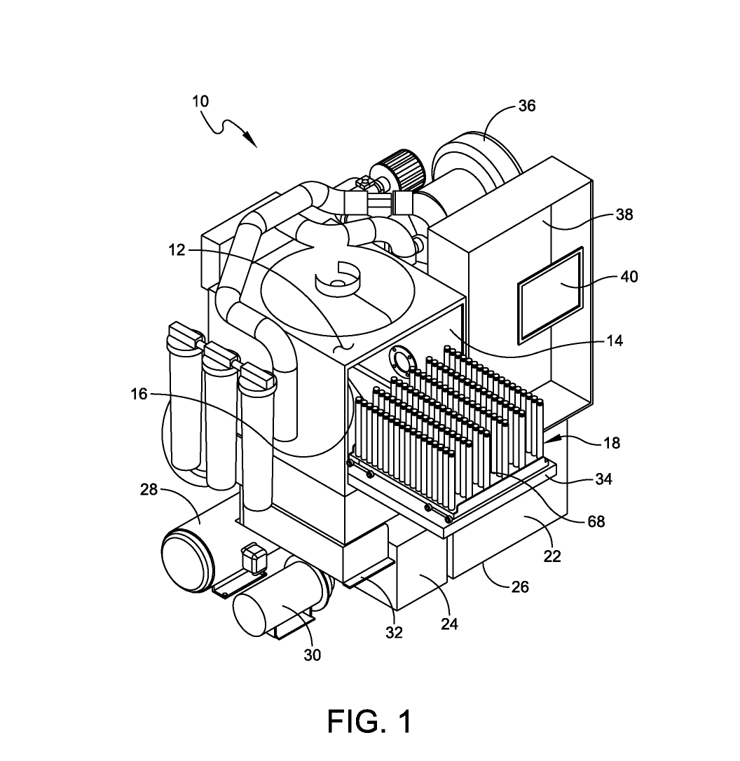

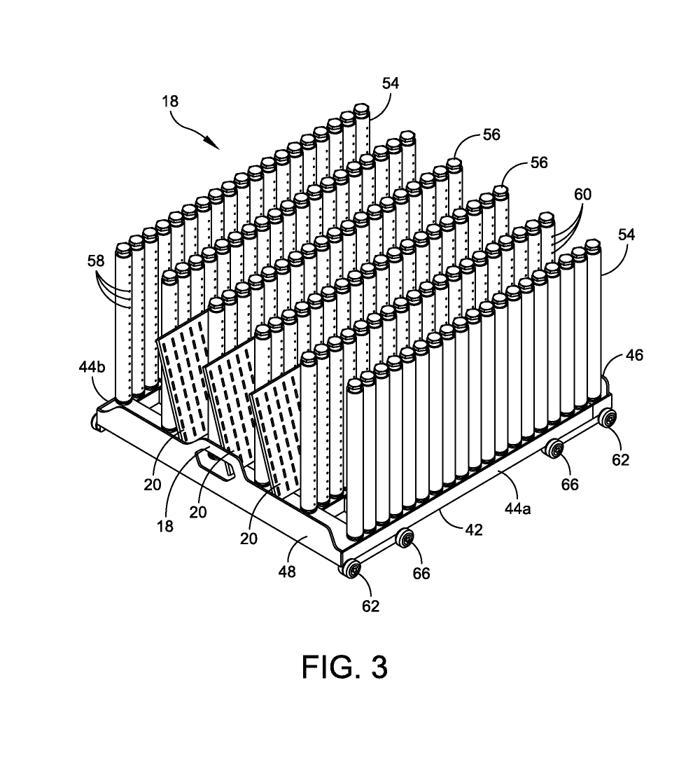

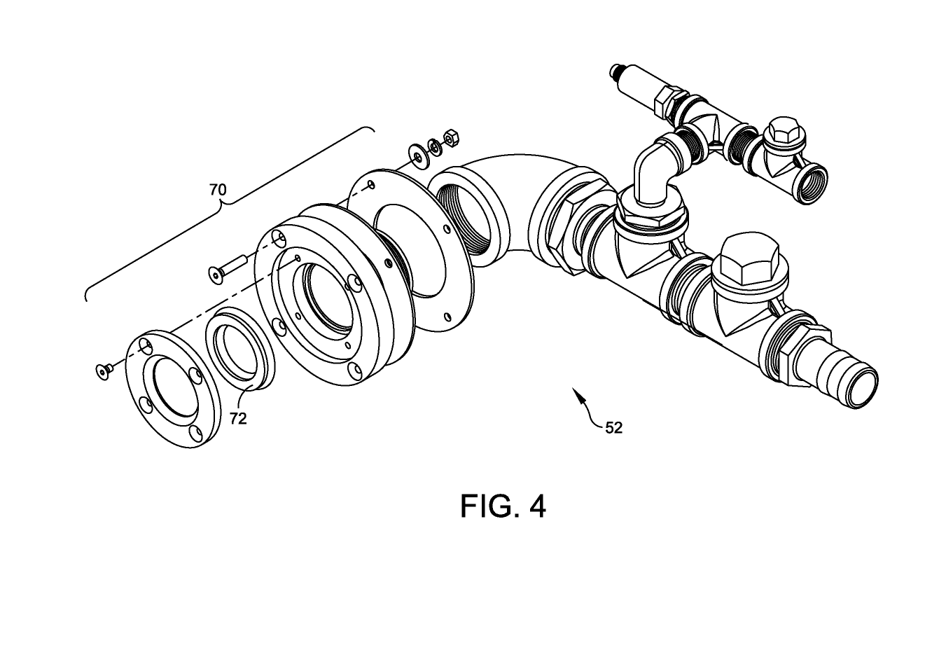

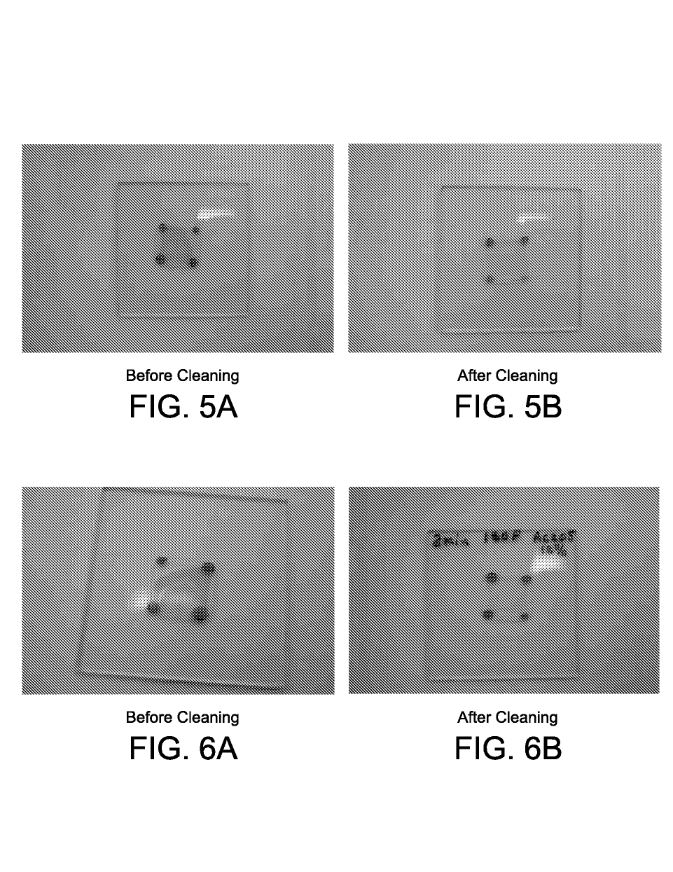

Referring now to the drawings, and more particularly to FIG. 1, a batch cleaning apparatus is generally indicated at 10. As shown, the batch cleaning apparatus 10 includes a housing 12 that is configured to support the various components of the batch cleaning apparatus. The housing 12 of the batch cleaning apparatus 10 has a process chamber 14 having an open front 16. The process chamber 14 is sized and shaped to slidably receive a fluid delivery manifold assembly, generally indicated at 18, therein. The arrangement is such that the fluid delivery manifold assembly 18 is configured to support printed circuit boards (20 in FIG. 3) in the manner described below to clean the printed circuit boards during a cleaning operation. The fluid delivery manifold assembly 18 can be rolled into and out of the process chamber to load and unload the printed circuit boards 20.

The housing 12 of the batch cleaning apparatus 10 further supports a wash tank 22 positioned below the process chamber 14 and an optional rinse tank 24 located next to the wash tank and below the process chamber at a base 26 of the housing. A wash pump 28 and an optional rinse pump 30 are supported by the housing 12 at the base 26 of the housing shown in FIG. 1. The wash pump 28 and the optional rinse pump 30 are provided to deliver fluid from the wash tank 22 and the optional rinse tank 24, respectively, to the fluid delivery manifold assembly 18. A cleaning fluid having a mild cleaner may be contained within the wash tank 22. A rinsing fluid may be contained within the optional rinse tank 24. The fluids delivered by the wash tank 22 and/or the optional rinse tank 24 to the fluid delivery manifold assembly 18 may be heated by a booster heater 32, which is located on the housing 12 next to the wash pump 28 and the optional rinse pump 30.

The housing 12 further includes a door 34 that is hinged at the bottom of the door to the housing so that when opened, the door supports the fluid delivery manifold assembly 18 in the manner shown in FIG. 1. In its closed position, the door 34 provides a watertight seal with the opening 16 of the process chamber 14. The fluid delivery manifold assembly 18 is configured to roll into and out of the process chamber 14 in the manner described in greater detail below.

The housing further includes a dryer motor 36, which provides the energy necessary to dry the printed circuit boards 20 after being washed and rinsed by the batch cleaning apparatus 10. A port (not designated) enables warm air to be delivered into the process chamber 14 to dry the substrates being processed therein. An electrical box 38 including a control system 40 is further provided to control the operation of the batch cleaning apparatus 10. The control system 40 may include a controller that is configured to be manipulated by an operator to control the operation of the batch cleaning apparatus 10.

As mentioned above, the fluid delivery manifold assembly 18 is capable of being removably disposed in the process chamber 14 of the housing 12. In one embodiment, and with further reference to FIGS. 2 and 3, the fluid delivery manifold assembly 18 includes a base 42 that defines a plurality of distribution manifolds, each indicated at 44. As shown, there are six distribution manifolds 44. The base 42 is rectangular in construction and includes two sides defined by the two outer distribution manifolds 44a, 44b and two ends defined by an inlet manifold 46 and a support member 48 (FIG. 3). A fluid inlet port 50 is provided in the inlet manifold 46. The fluid inlet port 50 is coupled to the wash tank 22 and/or the optional rinse tank 24 to deliver cleaning fluid and/or rinsing fluid to the fluid delivery manifold assembly 18 by a slip fit manifold coupler, which is generally indicated at 52 in FIGS. 1 and 4.

The fluid delivery manifold assembly includes a plurality of spray bars, each indicated at 54, which extend vertically upwardly from respective distribution manifolds 44. The spray bars 54 are spaced apart from one another a suitable distance to receive the printed circuit boards 20 therein. Specifically, the spray bars 54 are positioned to receive the printed circuit boards 20 and, along with the distribution manifolds 44, act as a rack or basket for processing the printed circuit boards. As shown, each distribution manifold 44 includes nineteen spray bars 54. It should be understood that the number of distribution manifolds 44 and the number of spray bars 54 may be varied to optimize the cleaning of the substrates 20. An open top end of each spray bar 54 is closed by a plug 56, which is designed to securely fit within the spray bar to prevent fluid from leaking out of the open end of the spray bar.

Each spray bar 54 of the two outer distribution manifolds 44a, 44b have orifices 58 located on one side of the spray bar, with the orifices being directed toward an adjacent row of spray bars to reduce overspray. Each spray bar 54 of the inner rows of spray bars have orifices 60 located on opposite sides of the spray bar to provide fluid contact to the substrates on both sides of the substrates 20. In a certain embodiment, the orifices 58, 60 formed in the spray bars 54 are round in shape and designed to discharge a solid spray stream, thereby maximizing the directional fluid movement and energy at the board surface. The arrangement is such that the spray bars 54 are positioned directly in front of and behind the intended substrates 20 to provide a direct fluid path to the substrates and to minimize deflection and to remove any shadowing effect.

The base 42 of the fluid delivery manifold assembly includes a plurality of rollers or wheels, each indicated at 62, which are each secured to a support bar 64 of the base by a wheel bolt 66. As shown, each side of the base 42 includes four wheels 62 that enable the fluid delivery manifold assembly 18 to be rolled into and out of the process chamber 14 of the batch cleaning apparatus 10. Thus, substrates, such as printed circuit boards 20, may be easily loaded into and unloaded from the fluid delivery manifold assembly 18. A handle 68 (FIG. 3) is provided to enable the operator to move the fluid delivery manifold assembly 18 into and out of the process chamber 14. The handle 68 is integrally formed as part of the support member 48 of the fluid delivery manifold assembly 18.

Referring now to FIG. 4, the slip fit manifold coupler 52 includes a fitting 70 that is designed to be removably coupled to the fluid inlet port 50 of the fluid delivery manifold assembly 18. The fitting 70 includes a seal 72 that provides a watertight seal between the fitting and the fluid inlet port 50 when connected. This construction enables pressurized fluid to be delivered from the tank (the wash tank 22 or the optional rinse tank 24) by the pump (the wash pump 28 or the rinse pump 30) and distributed to the distribution manifolds 44 located within the fluid delivery manifold assembly 18. Since the fluid delivery manifold assembly 18 must be rolled out of the process chamber 14 for loading and unloading of the assembly, the fluid inlet port 50 and the fitting 70 are designed to provide a water tight slip fit connection. In one embodiment, the fluid inlet port 50 and the slip fit manifold coupler 52 is located at the rear of the process chamber 14.

Referring to FIGS. 5A and 5B and to FIGS. 6A and 6B, a cleaning efficiency test was performed utilizing glass test coupons that represent a low standoff cleaning application. Lead-free flux was dispensed underneath the glass coupon with a two millimeter standoff height and reflowed. The test assembly was loaded into the fluid delivery manifold assembly 18 and processed. The coupons were visually inspected per IPC standards and passed. The test coupons were completely cleaned of all flux residues and were completely dry. The visual inspection was documented with a digital camera; the photos can be witnessed with respect to FIGS. 5A and 6A, which illustrate before photos, and to FIGS. 5B and 6B, which illustrate after photos.

During operation, the door 34 of the batch cleaning apparatus 10 is opened to provide access to the process chamber 14. The fluid delivery manifold assembly 18 is rolled to the position illustrated in FIG. 1 so that the door 34 supports the fluid delivery manifold assembly. Printed circuit boards 20 are loaded onto the fluid delivery manifold assembly 18 in the manner illustrated in FIG. 3 with circuit boards positioned between the spray bars 54. Once loaded, the fluid delivery manifold assembly 18 is rolled back into the process chamber 14 so that the fluid inlet port 50 is connected to the slip fit manifold coupler 52. The door 34 is closed and a batch cleaning operation may be performed. After performing the batch cleaning operation, the fluid delivery manifold assembly 18 is removed from the process chamber 14 by opening the door 34 and rolling the fluid delivery manifold assembly out of the process chamber. As discussed above, the orifices 58 of the spray bars 54 of the outer rows of spray bars are located on one side of the spray bars and the orifices 60 of the spray bars of the inner rows of spray bars are located on both sides of the spray bars. Thus, the spray bars 54 are positioned directly in front of and behind the printed circuit boards 20 to provide direct fluid application on the printed circuit boards.

It is to be clearly understood that the above description is intended by way of illustration and example only and is not intended to be taken by way of limitation, and that changes and modifications are possible. For example, the cleaning apparatus described above may be of a more traditional cleaning apparatus that is configured to include a conveyor to transport circuit boards through the cleaning apparatus. Accordingly, other embodiments are contemplated and modifications and changes could be made without departing from the scope of this application.

Thus, it should be observed that the fluid delivery manifold assembly of the batch cleaning apparatus enables efficient cleaning and rinsing fluid delivery to the printed circuit boards held by the assembly during a cleaning operation. The base of the fluid delivery manifold assembly has rollers along with a handle that allows the assembly to roll out of the process chamber for operators to load and unload products. A common fluid inlet port feeds six distribution manifolds, each having nineteen with nineteen spray bars. The distribution manifolds and the spray bars are positioned to provide support for intended product to be cleaned (for example, a substrate, such as a printed circuit board) and act as a rack or basket for processing products resting on edge. The spray bars are positioned directly in front of and behind the intended product to provide a direct fluid path to the product.

It should further be observed that the batch cleaning apparatus described herein having the fluid delivery manifold assembly reduces cleaning cycle times while maintaining industry standards for cleanliness. Prior fluid delivery manifolds lack the optimized energy, orientation and location of fluid discharge to efficiently clean residues from newer technology printed circuit board assemblies.

Having thus described several aspects of at least one embodiment of this disclosure, it is to be appreciated various alterations, modifications, and improvements will readily occur to those skilled in the art. Such alterations, modifications, and improvements are intended to be part of this disclosure, and are intended to be within the spirit and scope of the disclosure. Accordingly, the foregoing description and drawings are by way of example only.

For example, the number of holes, hole pattern, hole size, and hole shape in the spray bars may be varied. In addition, the placement and length of the spray bars in relation to the manifold may be changed to optimize the cleaning of the printed circuit boards. The number of holes, hole pattern, hole size and hole shape of the manifold ports and the size and connection orientation of the slip fit manifold intake can be varied as well.

What is claimed is:

1. A batch cleaning apparatus for cleaning printed circuit boards, the batch cleaning apparatus comprising:
a housing including a process chamber;
a fluid holding tank supported by the housing; and
a fluid delivery manifold assembly removably disposed in the process chamber of the housing and in fluid communication with fluid holding tank, the fluid delivery manifold assembly including
a fluid inlet port selectively coupled to the fluid holding tank,
a plurality of distribution manifolds in fluid communication with the fluid inlet port, and
a plurality of spray bars in fluid communication with the distribution manifolds, the spray bars being configured to provide support for printed circuit boards during a cleaning operation.

2. The batch cleaning apparatus of claim 1, wherein the fluid delivery manifold assembly further includes a base and a handle secured to the base and configured to move the fluid delivery manifold assembly.

3. The batch cleaning apparatus of claim 2, wherein the fluid delivery manifold assembly further includes a plurality of rollers secured to the base and configured to roll the fluid delivery manifold assembly into and out of the process chamber.

4. The batch cleaning apparatus of claim 1, wherein the spray bars are positioned directly in front of and behind the printed circuit boards to provide a direct fluid path to the printed circuit boards during operation of the batch cleaning apparatus.

5. The batch cleaning apparatus of claim 1, wherein orifices of spray bars of an outer row of spray bars are located on one side of the spray bars.

6. The batch cleaning apparatus of claim 5, wherein orifices of spray bars of an inner row of spray bars are located on both sides of the spray bars.

7. The batch cleaning apparatus of claim 1, further comprising a slip fit manifold coupler connected to and in fluid communication with the fluid inlet port of the fluid delivery manifold assembly.

8. The batch cleaning apparatus of claim 1, further comprising a pump to provide movement of fluid from the fluid holding tank to the fluid delivery manifold assembly.

9. The batch cleaning apparatus of claim 1, further comprising an electromechanical control system to control the operation of the batch cleaning apparatus.

10. A method for batch cleaning printed circuit boards, the method comprising:
providing a batch cleaning apparatus including a housing including a process chamber, a fluid holding tank supported by the housing, and a fluid delivery manifold assembly removably disposed in the process chamber of the housing and in fluid communication with fluid holding tank, the fluid delivery manifold assembly including a fluid inlet port selectively coupled to the fluid holding tank, a plurality of distribution manifolds in fluid communication with the inlet port, and a plurality of spray bars in fluid communication with the distribution manifolds, the spray bars being configured to provide support for printed circuit boards during a cleaning operation;
loading printed circuit boards on the fluid delivery manifold assembly in a position in which the printed circuit boards are positioned between the spray bars; and
performing a batch cleaning operation.

11. The method of claim 10, further comprising rolling the fluid delivery manifold assembly into the process chamber after loading printed circuit boards.

12. The method of claim 11, further comprising rolling the fluid delivery manifold assembly out of the process chamber after performing the batch cleaning operation.

13. The method of claim 10, wherein orifices of the spray bars of an outer row of spray bars are located on one side of the spray bars and the spray bars of an inner row of spray bars have orifices located on both sides of the spray bars.

14. The method of claim 10, further comprising positioning the spray bars directly in front of and behind the printed circuit boards to provide a direct fluid path to the printed circuit boards.

15. The method of claim 10, further comprising connecting the fluid delivery manifold assembly to the fluid holding tank by a slip fit manifold coupler.

16. A batch cleaning apparatus for cleaning printed circuit boards, the batch cleaning apparatus comprising:
a housing including a process chamber;
a fluid holding tank supported by the housing; and
a fluid delivery manifold assembly removably disposed in the process chamber of the housing and in fluid communication with fluid holding tank, the fluid delivery manifold assembly including
a base and a handled secured to the base and configured to lift the fluid delivery manifold assembly;
a plurality of distribution manifolds supported by the base;
a fluid inlet port selectively coupled to the fluid holding tank and in fluid communication with the plurality of distribution manifolds; and
a plurality of spray bars in fluid communication with the distribution manifolds.

17. The batch cleaning apparatus of claim 16, wherein the spray bars of the fluid delivery manifold assembly are configured to provide support for printed circuit boards during a cleaning operation.

18. The batch cleaning apparatus of claim 16, wherein the fluid delivery manifold assembly further includes a plurality of rollers secured to the base and configured to roll the fluid delivery manifold assembly out of the process chamber.

19. The batch cleaning apparatus of claim 16, further comprising a slip fit manifold coupler connected to and in fluid communication with the fluid inlet port of the fluid delivery manifold assembly.
